(19) United States
(12) Patent Application Publication
(10) Pub. No.: US 2023/0387333 A1
(43) Pub. Date: Nov. 30, 2023

(54) PHOTODETECTOR STRUCTURE WITH INSULATIVE COLLAR AND RELATED METHODS

(71) Applicant: GlobalFoundries U.S. Inc., Malta, NY (US)

(72) Inventors: Siva P. Adusumilli, South Burlington, VT (US); John J. Ellis-Monaghan, Grand Isle, VT (US); Rajendran Krishnasamy, Essex Junction, VT (US); Ramsey Hazbun, Colchester, VT (US)

(21) Appl. No.: 17/664,741

(22) Filed: May 24, 2022

(51) Int. Cl. H01L 31/0216; H01L 31/18; H01L 31/105

(52) U.S. Cl. CPC H01L 31/0216; H01L 31/1804; H01L 31/105; H01L 31/022408

(57) ABSTRACT

A photodetector structure includes a first semiconductor material layer on a first portion of a doped well in a substrate. The photodetector structure includes a second semiconductor layer over the first semiconductor layer. The first and second semiconductor material layers may include an undoped semiconductor material. The photodetector structure includes an insulative collar laterally surrounding the first and second semiconductor material layers. The insulative collar may include a varying horizontal thickness. The photodetector structure includes a doped semiconductor material having an opposite doping polarity relative to the doped well, and positioned over the second semiconductor material layer and the insulating collar.

### BACKGROUND

The present disclosure relates to photonics, and more specifically, to photodetector structures and related methods.

A “PIN photodetector” is a diode with an undoped intrinsic semiconductor region between a p-typed semiconductor and an n-type semiconductor region. PIN photodetector performance may be inhibited by dark current, which is a small electric current that flows through photosensitive devices even when no photons are entering the device and is a primary source of noise in photonic sensors. Dark current, when present, may have negative effects on photodetector performance.

### SUMMARY

An aspect of the disclosure is directed to a photodetector structure, including: a first semiconductor layer on a first portion of a doped well in a substrate; an insulative collar laterally surrounding the first semiconductor layer, the insulative collar on the first portion of the doped well between the first semiconductor layer and a second portion of the doped well; and a second semiconductor layer over the first semiconductor layer, the insulative collar laterally surrounds the second semiconductor layer.

Another aspect of the disclosure includes a photodetector structure, including: a first semiconductor layer on a first portion of a doped well in a substrate, the first semiconductor layer including epitaxial silicon; an insulative collar laterally surrounding the first semiconductor layer, the insulative collar on the first portion of the doped well between the first semiconductor layer and a second portion of the doped well; a second semiconductor layer over the first semiconductor layer, the second semiconductor layer including epitaxial germanium, the insulative collar laterally surrounds the second semiconductor layer; a third semiconductor layer over the second semiconductor layer, the third semiconductor layer including epitaxial silicon; and a doped semiconductor material over the third semiconductor layer and the insulative collar, the doped semiconductor material having an opposite doping polarity relative to the doped well.

An aspect of the disclosure related to a method of forming a photodetector structure, the method including: forming a first semiconductor layer on a first portion of a doped well in a substrate; forming an insulative collar laterally surrounding the first semiconductor layer, the insulative collar on the first portion of the doped well between the first semiconductor layer and a second portion of the doped well; and forming a second semiconductor layer over the first semiconductor layer, the insulative collar laterally surrounds the second semiconductor layer.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a preliminary structure to be processed, according to embodiments of the disclosure;

FIG. 2 shows a cross-sectional view of processing a first insulative layer according to embodiments of the disclosure;

FIG. 3 shows a cross-sectional view of forming an insulative layer according to embodiments of the disclosure;

FIG. 4 shows a cross-sectional view of forming an insulative collar according to embodiments of the disclosure;

FIG. 5 shows a cross-sectional view of forming a first undoped semiconductor layer according to embodiments of the disclosure;

FIG. 6 shows a cross-sectional view of forming a second undoped semiconductor layer according to embodiments of the disclosure;

FIG. 7 shows a cross-sectional view of forming a third undoped semiconductor layer according to embodiments of the disclosure;

FIG. 8 shows a cross-sectional view of forming a doped semiconductor material according to embodiments of the disclosure;

FIG. 9 shows a cross-sectional view of a photodetector structure according to embodiments of the disclosure;

FIG. 10 shows a cross-sectional view of a photodetector structure according to further embodiments of the disclosure;

FIG. 11 shows a cross-sectional view of a photodetector structure according to further embodiments of the disclosure;

FIG. 12 shows a cross-sectional view of a photodetector structure according to further embodiments of the disclosure; and

FIG. 13 shows a cross-sectional view of a photodetector structure within a trench isolation structure according to further embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

A photodetector structure according to embodiments of the disclosure may provide, e.g., a stack of undoped semiconductor layers on a first portion of a doped well. The photodetector structure may include an insulative collar horizontally between a stack of undoped semiconductor layer and a second portion of a doped well. The photodetector structure may include a doped semiconductor material on a stack of undoped semiconductor layers and an insulative collar. The stack of undoped semiconductor layers may form an intrinsic region between the doped well having a first doping polarity and the doped semiconductor material having a second doping polarity opposite the first doping polarity.

In some embodiments, a stack of undoped semiconductor layers may include a first silicon layer on a first portion of a doped well, a germanium layer over the first silicon layer, and a second silicon layer over the germanium layer. The first silicon layer and the second silicon layer may include epitaxial silicon (epi-Si), and the germanium layer may include epitaxial germanium (epi-Ge).

In some embodiments, a photodetector structure may include a first contact structure electrically coupled to a doped semiconductor material and a second contact structure electrically coupled to a doped well. The second contact structure may bias the doped well to reduce dark currents from forming in the photodetector, and thus improve performance as compared to other photodetector structures.

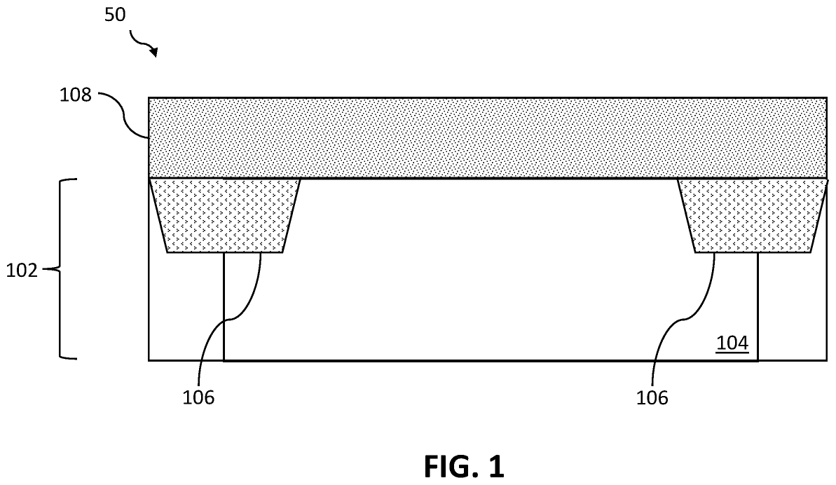

Referring to FIG. 1, a preliminary structure 50 to form a photodetector structure according to embodiments of the disclosure is shown. Preliminary structure 50 may be processed as described herein to yield a photodetector structure according to embodiments of the disclosure. However, it is understood that other techniques, ordering of processes, etc., alternatively may be implemented to yield a photodetector according to the disclosure. FIG. 1 shows a cross-section view of preliminary structure 50 with a substrate 102, e.g., one or more semiconductor materials. Substrate 102 may include but is not limited to silicon, germanium, silicon germanium, silicon carbide, or any other common semiconductor substrates. A portion or entire semiconductor substrate 102 may be strained.

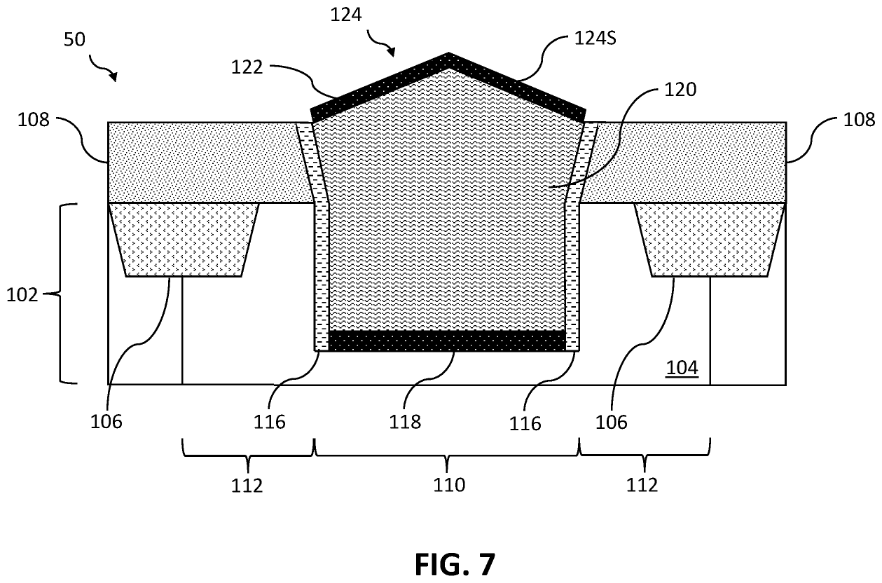

For purposes of reference, a doped well 104 within substrate 102 of preliminary structure 50 is illustrated. Preliminary structure 50 may include one or more trench isolation structures 106 within substrate 102. Each trench isolation structure 106 may include a trench etched into substrate 102 and filled with an insulating material such as oxide, insulative semiconductor, etc., to isolate one region of the substrate from an adjacent region of the substrate. Substrate 102 may include a variety of doped wells therein for formation of different polarity photodetector structures. Doped well 104 includes a first dopant type formed using any appropriate n-type or p-type dopant and may be formed using any now known or later developed technique (e.g., in-situ doping or ion implantation). As described herein, subsequent processing of preliminary structure 50 may include forming a second doped region (FIG. 7) having an opposite doping polarity than doped well 104 to define a “PIN photodetector.” The term “PIN” refers to two regions having different types of conductivity (i.e., P-type and N-type), which may be induced through dopants within the two regions, that are separated by an intrinsic region having undoped semiconductor material (i.e., I-Type) therein.

Preliminary structure 50 may include an insulative layer 108 over substrate 102. Insulative layer 108 may be formed of, e.g., any now known or later developed insulative material such as but not limited to oxides. Insulative layer 108 may be formed using deposition and/or any other technique to form a material on substrate 102.

As used herein, “depositing” may include any now known or later developed techniques appropriate for the material to be deposited including but are not limited to: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

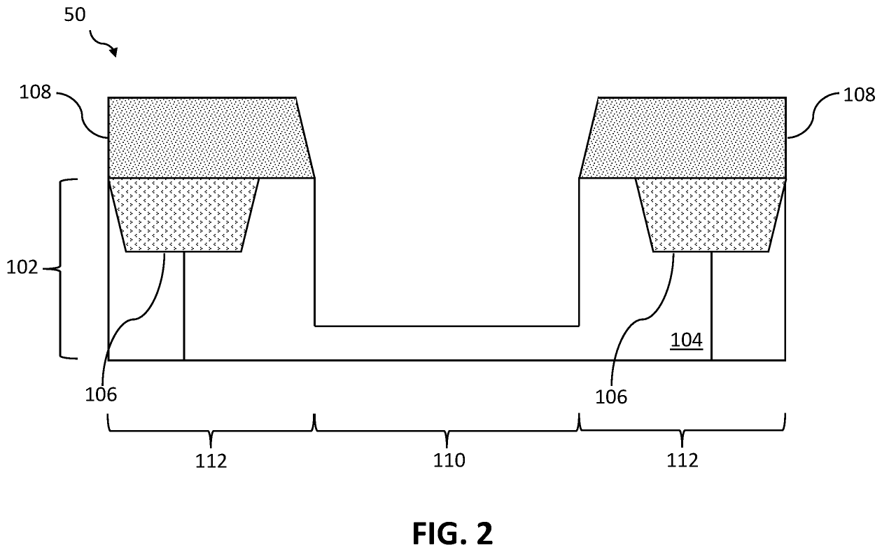

Referring now to FIG. 2, embodiments of the disclosure may include removing portions of insulative layer 108 using, e.g., a mask (not shown) with an opening at a targeted position to expose insulative layer 108. This removal process may include, forming a mask patterned to expose selected portion(s) of insulative layer 108. Masks may include any now known or later developed appropriate masking material, e.g., a nitride hard mask. Any appropriate etching process, e.g., a reactive ion etch (RIE), can remove selected portion(s) of insulative layer 108. As shown in FIG. 2, continued processing may include removing portions of insulative layer 108 and substrate 102 thereunder to yield a first portion 110 of doped well 104 and a second portion 112 of doped well 104. Insulative layer 108 is selectively removed from first portion 110 of doped well 104, and remnants of insulative layer 108 are over second portion 112 of doped well 104.

As discussed herein, insulative layer 108 may be removed, in part, by etching. Etching generally refers to the removal of material from a substrate (or structures formed on the substrate) and is often performed with a mask in place so that material may selectively be removed from certain areas of the substrate, while leaving the material unaffected, in other areas of the substrate. There are generally two categories of etching, (i) wet etch and (ii) dry etch. Wet etch is performed with a solvent (such as an acid) which may be chosen for its ability to selectively dissolve a given material (such as oxide), while leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g., silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases, which approach the wafer approximately from one direction, and therefore this process is highly anisotropic. Reactive ion etching (RIE) operates under conditions intermediate between sputter and plasma etching and may be used to produce deep, narrow features, such as shallow trench isolation (STI) trenches. In this case, a RIE may be used, for example.

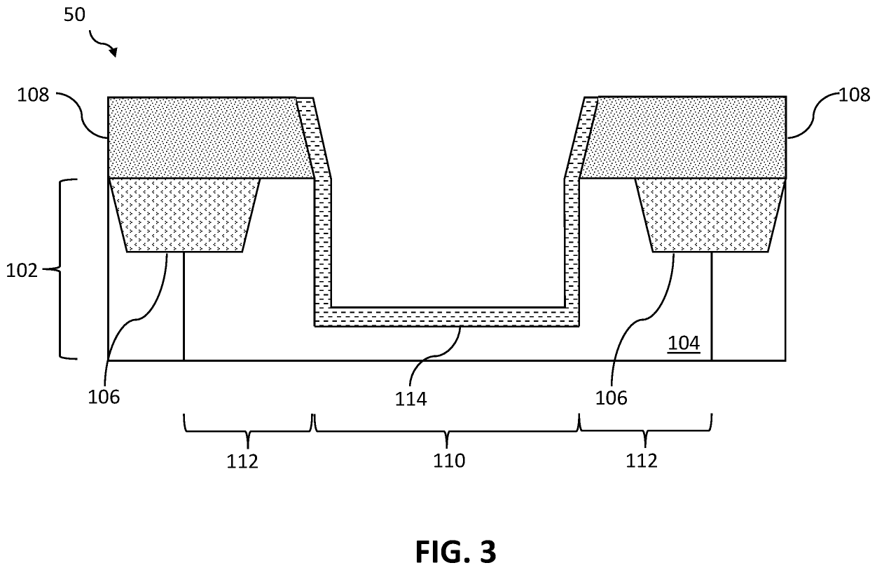

Referring now to FIG. 3, embodiments of the disclosure may include depositing an insulative material 114 over exposed materials to cover exposed portions of doped well 104, e.g., upper surfaces of first portion 110 and sidewalls of second portion 112 and/or remaining insulative layer 108. Insulative material 114 may include an oxide, insulative semiconductor, etc., to isolate one region within substrate 102 from an adjacent region(s) and may have a composition similar to or different from insulative layer 108.

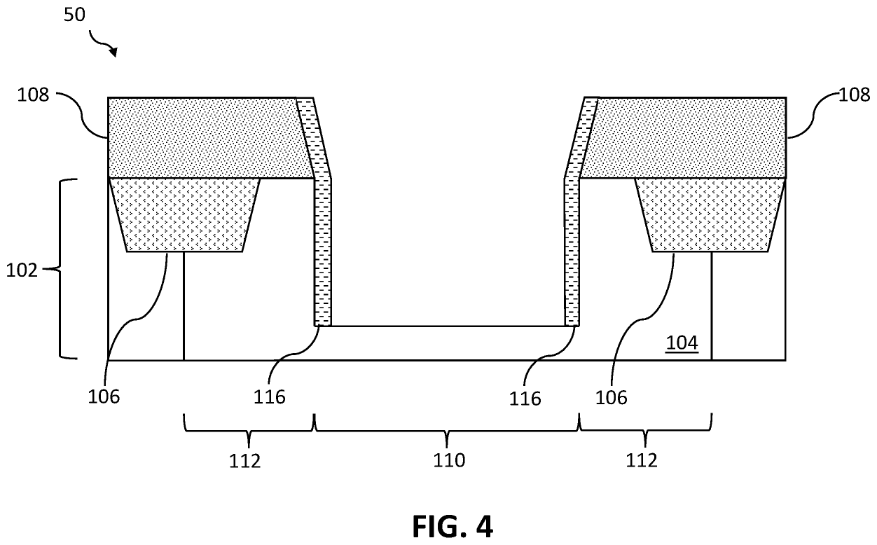

Turning to FIG. 4, additional processing, e.g., of insulative material 114 may include selectively removing portions of insulative material 114 from portions of substrate 102. For example, as shown in FIG. 4, embodiments of the disclosure may include selectively removing portions of insulative material 114 over first portion 110 of doped well 104 to yield an insulative collar 116. Insulative collar 116 may remain over at least part of first portion 110 and horizontally abut second portion 112 of doped well 104 to electrically isolate doped well 104 from additional components formed in subsequent processing. In the present embodiment, insulative collar 116 includes a substantially uniform horizontal thickness throughout. In other embodiments, insulative collar 116 may include a varying horizontal thickness, and thus may be relatively thick or thin at various locations.

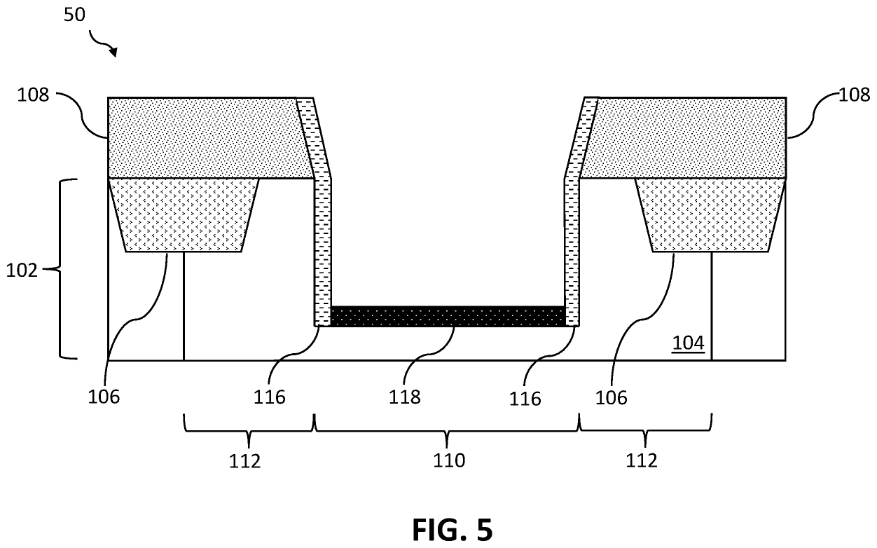

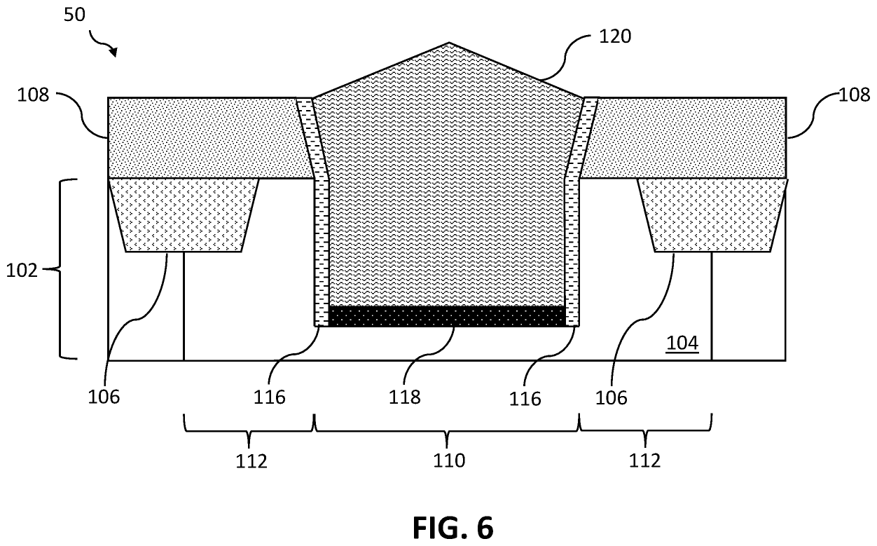

Referring now to FIGS. 5-7, embodiments of the disclosure may include forming a stack of undoped semiconductor layers 124 (FIG. 7 only) on first portion 110 of doped well 104 and horizontally adjacent to trench isolation structures 106. Insulative collar 116 may be separate stack of undoped semiconductor layers 124 from first portion 110 and second portion 112 of doped well 104. Stack of undoped semiconductor layers 124 may include a non-planar upper surface 124S (FIG. 7 only) that is above insulative collar 116 and doped well 104. Forming stack of undoped semiconductor layers 124 may include forming a first undoped semiconductor layer 118 (FIGS. 5-7), a second undoped semiconductor layer 120 (FIGS. 6, 7), and a third undoped semiconductor layer 122 (FIG. 7). For example, as shown by FIG. 5, embodiments of the disclosure may include forming first undoped semiconductor layer 118 on first portion 110 of doped well 104. As shown by FIG. 6, embodiments of the disclosure may include forming second undoped semiconductor layer 120 over first undoped semiconductor layer 118. As shown by FIG. 7, embodiments of the disclosure may include forming third undoped semiconductor layer 122 over second undoped semiconductor layer 120.

First undoped semiconductor layer 118 may include semiconductor material such as, but not limited to, epitaxial silicon (epi-Si). Second undoped semiconductor layer 120 may include semiconductor material such as, but not limited to, epitaxial germanium (epi-Ge). Third undoped semiconductor layer 122 may include semiconductor material such as, but not limited to, epitaxial silicon (epi-Si). Stack of undoped semiconductor layers 124 therefore may include a first silicon layer, a germanium layer, and a second silicon layer, e.g., first undoped semiconductor layer 118, second undoped semiconductor layer 120, and third undoped semiconductor layer 122.

The term “undoped semiconductor,” as used herein, refers to an intrinsic semiconductor material without any significant dopant species present (i.e., I-Type). Each of the undoped semiconductor layers 118, 120, 122 include intrinsic semiconductor material without any significant dopant species present. Stack of undoped semiconductor layers 124 may form an intrinsic region between two doped semiconductor regions having opposite doping polarity to form a PIN photodetector structure with insulative collar 116.

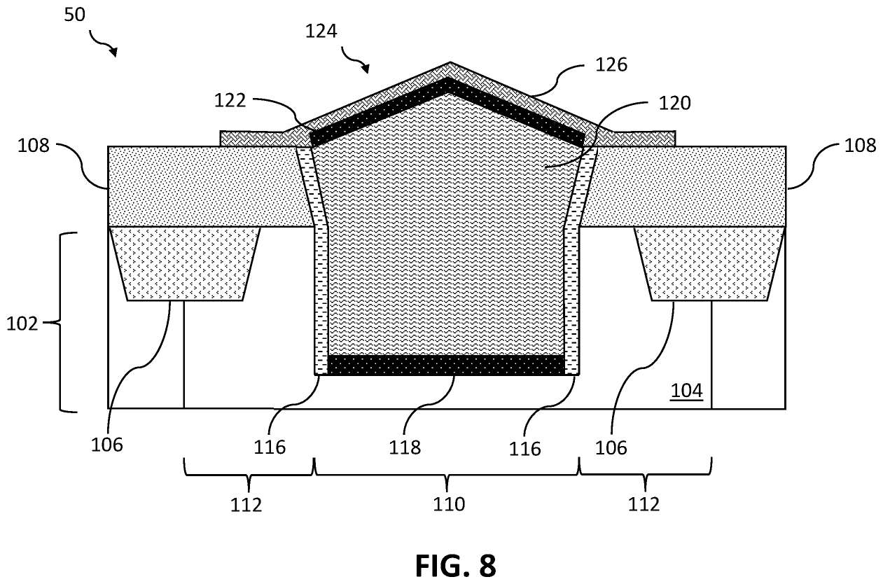

Turning to FIG. 8, embodiments of the disclosure may include depositing a doped semiconductor material 126 to cover stack of undoped semiconductor layers 124 and insulative layer 108. Insulative layer 108 is vertically between doped semiconductor material 126 and doped well 104. Doped semiconductor material 126 may include semiconductor material such as, but not limited to, polysilicon (poly-Si). Additional processing, e.g., etching, of doped semiconductor material 126 may include using a mask (not shown) to selectively remove portions of doped semiconductor material 126 from targeted portions of insulative layer 108.

Doped semiconductor material 126 may include a doped semiconductor material formed using any appropriate n-type or p-type dopant and may be formed using any now known or later developed technique (e.g., in-situ doping or ion implantation). Doped semiconductor material 126 may include n-type dopant such as but not limited to: phosphorous (P), arsenic (As), antimony (Sb). Doped semiconductor material 126 may include p-type dopants such as but not limited to: boron (B), indium (In) and gallium (Ga). Any necessary thermal process may be carried out to drive in the dopants. Doped semiconductor material 126 may include an opposite doping polarity relative to doped well 104. Similar n-type or p-type dopants may be used for doped well 104. For example, doped semiconductor material 126 may include a n-type dopant and doped well 104 may include a p-type dopant. In other embodiments, doped semiconductor material 126 may include a p-type dopant and doped well 104 may include a n-type dopant.

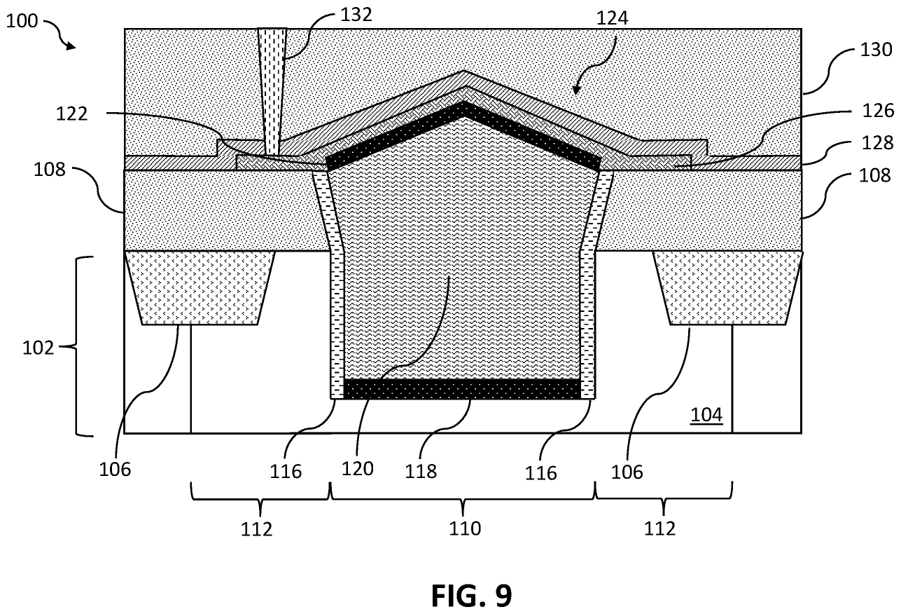

Turning now to FIG. 9, embodiments of the disclosure may include additional processing to form photodetector structure 100. Forming photodetector structure 100 may include, for example, forming a nitride cap 128 over doped semiconductor material 126 and depositing an insulative material 130 over exposed surfaces. Insulative material 130 may include, for example, an oxide or any other appropriate interlayer dielectric material. The method may include forming a contact structure 132 electrically coupled to doped semiconductor material 126. Any appropriate middle-of-line (MOL) and back-end-of-line (BEOL) processing may be carried out to form contact structures 132 to doped semiconductor material 126. As the processes to form nitride caps and contact structures are well known, no further details will be provided. Any necessary etch stop layers, e.g., single, or dual contact etch stop layers, may be employed, and any silicidation can be carried out as known in the field as part of the processes.

FIG. 9 depicts one embodiment of photodetector structure 100. In the present embodiment, photodetector structure 100 includes stack of undoped semiconductor layers 124 on first portion 110 of doped well 104 and horizontally adjacent to trench isolation structures 106. Stack of undoped semiconductor layers 124 includes first undoped semiconductor layer 118, second undoped semiconductor layer 120, and third undoped semiconductor layer 122. First and third undoped semiconductor layers 118, 122 may include epi-Si, and second undoped semiconductor layer 120 may include epi-Ge. Photodetector structure 100 includes insulative collar 116 on first portion 110 of doped well 104, such that insulative collar separates stack of undoped semiconductor layers 124 from first portion 110 and second portion 112 of doped well 104. Insulative collar 116 may include, for example, an oxide, having a substantially uniform horizontal thickness throughout. Photodetector structure 100 includes insulative layer 108 over doped well 104 and laterally surrounding at least a portion of stack of undoped semiconductor layers 124. For instance, insulative layer 108 may be on first portion 110 of doped well 104 and laterally surrounding first undoped semiconductor layer 118.

Photodetector structure 100 includes doped semiconductor material 126 over stack of undoped semiconductor layers 124, insulative collar 116, and insulative layer 108. Doped semiconductor material 126 may include polysilicon (poly-Si) having an opposite doping polarity relative to doped well 104. Doped semiconductor material 126 may include n-type or p-type dopants. Stack of undoped semiconductor layers 124 forms an intrinsic region between doped well 104 and doped semiconductor material 126 to form a PIN photodetector. Photodetector structure 100 includes contact structure 132 electrically coupled to doped semiconductor material 126. Contact structure 132 extends through nitride cap 128 and insulative layer 130. Contact structure 132 may couple photodetector structure 100 to one or more other electronic components (not shown). Photodetector structure 100 may be part of a photonics integrated circuit (PIC) that includes one or more other electrical devices (not shown).

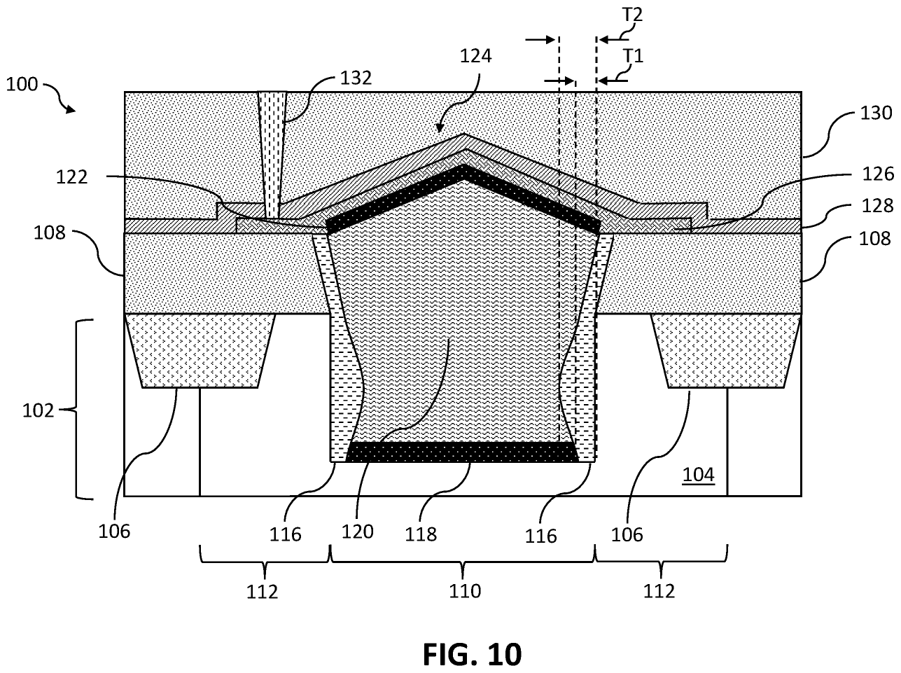

FIG. 10 depicts another embodiment of photodetector structure 100 in which the thickness of insulative collar 116 varies at different positions. Photodetector structure 100 is substantially similar to the embodiment described in FIG. 9 but may have varying thickness between second portion 112 of doped well 104 and stack of undoped semiconductor layers 124. Insulative collar 116 may include a first portion having a first horizontal thickness T1, and a second portion having a second horizontal thickness T2 greater than first horizontal thickness T1. Accordingly, second undoped semiconductor layer 120 has a varying horizontal width along a vertical extent of stack of undoped semiconductor layers 124. Although insulative collar 116 is depicted as having first and second horizontal thicknesses T1, T2, insulative collar 116 may include two or more thicknesses at two or more locations throughout.

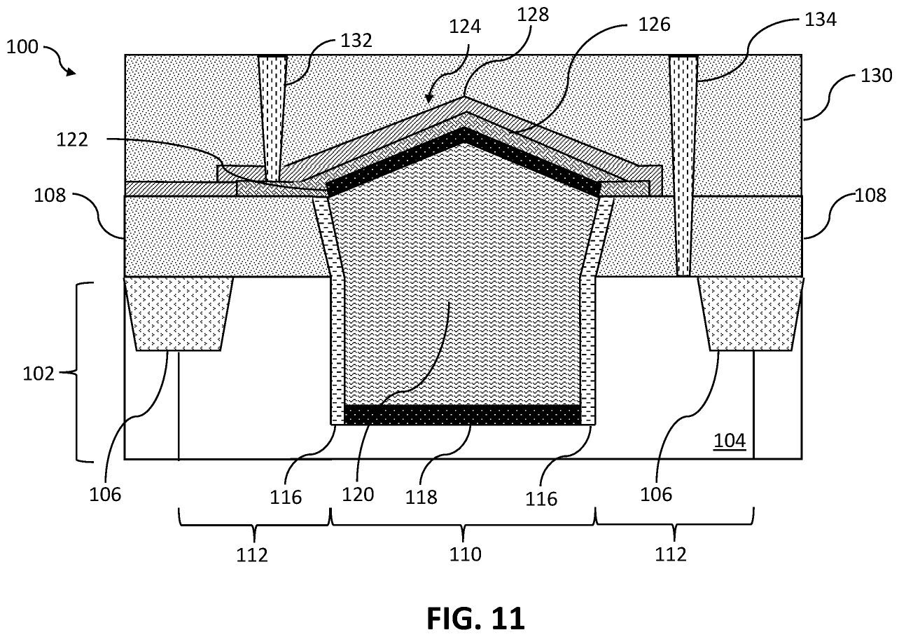

FIG. 11 depicts another embodiment of photodetector structure 100 including a second contact structure 134 electrically coupled to doped well 104. Photodetector structure 100 is substantially similar to the embodiment described in FIG. 9, with second contact structure 134 coupled to doped well 104 to bias doped well 104. Biasing doped well 104 using second contact structure 134 may uniformly distribute electrical potential in photodetector structure 100. Biasing doped well 104 may lower dark current relative to embodiments without biasing.

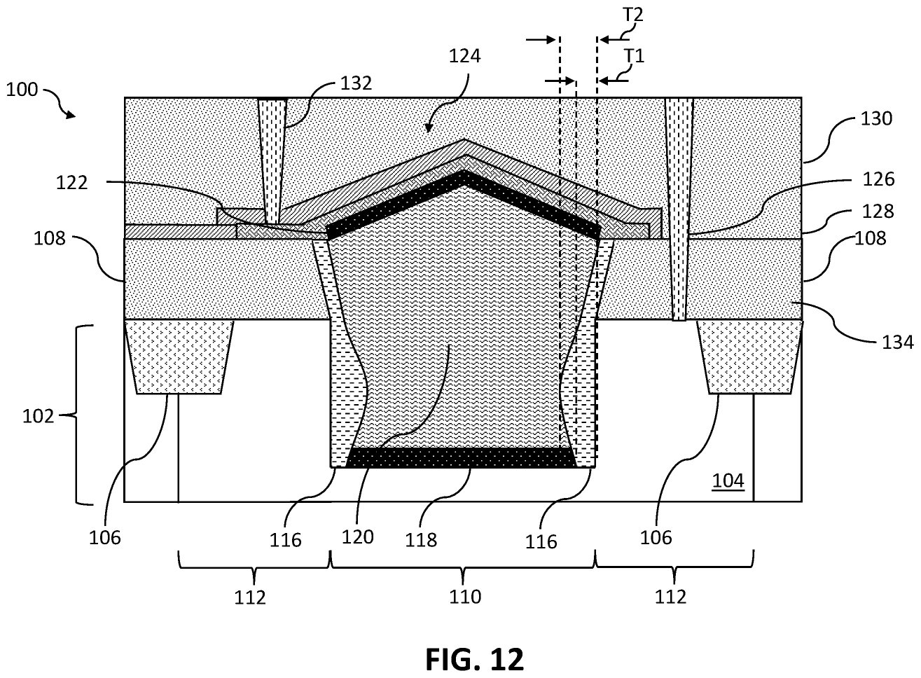

FIG. 12 depicts another embodiment of photodetector structure 100, including second contact structure 134 electrically coupled to doped well 104 and insulative collar 116 having a varying horizontal thickness. Photodetector structure 100 is substantially similar to the embodiment described in FIG. 11 but includes a varying horizontal thickness as described above regarding FIG. 10.

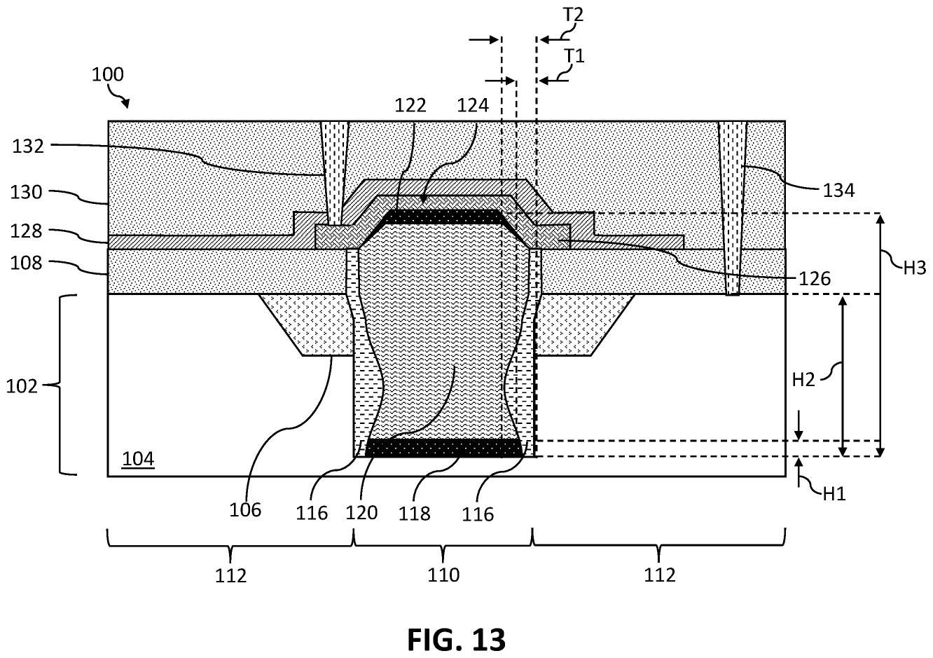

FIG. 13 depicts another embodiment of photodetector structure 100 including stack of undoped semiconductor layers 124 positioned within trench isolation structure 106. Forming stack of undoped semiconductor layers 124 within trench isolation structure 106 includes selectively removing portions of trench isolation structure 106 to form first portion 110 of doped well 104 within and below trench isolation structure 106. Selectively removing portions of trench isolation structure 106 may include using, e.g., a mask (not shown) to expose a target portion of trench isolation structure 106. Stack of undoped semiconductor layers 124 includes first undoped semiconductor layer 118 having a first height H1 above first portion 110 of doped well 104. Trench isolation structure 106 has a second height H2 above first portion 110 of doped well 104 greater than first height H1 of first undoped semiconductor layer 118. Stack of undoped semiconductor layers 124 includes second undoped semiconductor layer 122 having a third height H3 above first portion 110 of doped well 104 greater than second height H2 of trench isolation structure 106.

As further shown by FIG. 13, photodetector structure 100 includes contact structure 132 electrically coupled to doped semiconductor material 126 and second contact structure 134 electrically coupled to doped well 104. Contact structure 132 may couple photodetector structure 100 to one or more other electronic components (not shown). Second contact structure 134 couples to doped well 104 to bias doped well 104. Biasing doped well 104 using second contact structure 134 may uniformly distribute electrical potential in photodetector structure 100. Biasing doped well 104 may lower dark current relative to embodiments without biasing. In other embodiments, photodetector structure 100 does not include second contact structure 134.

As further shown by FIG. 13, photodetector structure 100 includes insulative collar 116 in which thickness of insulative collar 116 varies at different positions. Insulative collar 116 may include a first portion having first horizontal thickness T1, and a second portion having second horizontal thickness T2 greater than first horizontal thickness T1. Accordingly, second undoped semiconductor layer 120 has a varying horizontal width along a vertical extent of stack of undoped semiconductor layers 124. Although insulative collar 116 is depicted as having first and second horizontal thicknesses T1, T2, insulative collar 116 may include two or more thicknesses at two or more locations throughout. In other embodiments, thickness of insulative collar 116 is uniform throughout.

Embodiments of the present disclosure provide technical and commercial advantages, and some examples of such advantages are described herein. Embodiments of the disclosure may improve operational performance for photodetector structures by lowering dark current and improve quantum efficiency. Insulative collar 116 may improve dark current relative to photodetector structures without insulative collar 116. Second contact structure 134 may bias doped well 104 to distribute electrical potential uniformly, or substantially uniformly, throughout photodetector structure 100 relative to unbiased doped wells having electrical potential concentrated within a portion of an intrinsic region.

The photodetector structure 100 as described above receives optical signals, e.g., infrared, from a transmission source (not shown). The transmission source may include light-transmissive materials configured to direct optical signals to photodetector structure 100. Photodetector structure 100 coverts those optical signals into electrical signals using doped well 104, stack of undoped semiconductor layers 124, and doped semiconductor 126. These electrical signals may be transmitted from photodetector structure 100 to one or more other electrical devices (not shown) through contact structure 132.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing structures as part of either (a) an intermediate product, such as a motherboard, or (b) an end product. The end product can be any product that includes integrated circuit chips, ranging from toys and other low-end applications to advanced computer products having a display, a keyboard or other input structure, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” or “substantially” as applied to a particular value of a range applies to both values, and unless otherwise dependent on the precision of the instrument measuring the value, may indicate+/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A photodetector structure, comprising:
a first semiconductor layer on a first portion of a doped well in a substrate;
an insulative collar laterally surrounding the first semiconductor layer, the insulative collar on the first portion of the doped well between the first semiconductor layer and a second portion of the doped well; and
a second semiconductor layer over the first semiconductor layer, wherein the insulative collar laterally surrounds the second semiconductor layer.

2. The photodetector structure of claim 1, further comprising:
a third semiconductor layer over the second semiconductor layer; and
a doped semiconductor material over the third semiconductor layer and the insulative collar, the doped semiconductor material includes polysilicon having an opposite doping polarity relative to the doped well,
wherein the insulative collar includes an oxide.

3. The photodetector structure of claim 2, wherein the first semiconductor layer includes epitaxial silicon, the second semiconductor layer includes epitaxial germanium, and the third semiconductor layer includes epitaxial silicon.

4. The photodetector structure of claim 2, wherein the first, second, and third semiconductor layers are horizontally adjacent to a trench isolation structure.

5. The photodetector structure of claim 2, wherein the first, second, and third semiconductor layers are positioned within a trench isolation structure.

6. The photodetector structure of claim 5, wherein the first semiconductor layer has a first height above the first portion of the doped well, the trench isolation structure has a second height above the first portion of the doped well greater than the first height, and the second semiconductor layer has a third height above the first portion of the doped well greater than the second height.

7. The photodetector structure of claim 1, wherein an upper surface of the second semiconductor layer is above the insulative collar relative to the doped well.

8. The photodetector structure of claim 2, further comprising:
a first insulative layer vertically between the doped semiconductor material and the doped well, the first insulative layer horizontally adjacent to each of the first, second, and third semiconductor layers; and
a first contact structure electrically coupled to the doped semiconductor material.

9. The photodetector structure of claim 8, further comprising a second contact structure electrically coupled to the doped well, wherein the doped well is biased by the second contact structure.

10. A photodetector structure, comprising:
a first semiconductor layer on a first portion of a doped well in a substrate, the first semiconductor layer including epitaxial silicon;
an insulative collar laterally surrounding the first semiconductor layer, the insulative collar on the first portion of the doped well between the first semiconductor layer and a second portion of the doped well;
a second semiconductor layer over the first semiconductor layer, the second semiconductor layer including epitaxial germanium, wherein the insulative collar laterally surrounds the second semiconductor layer;
a third semiconductor layer over the second semiconductor layer, the third semiconductor layer including epitaxial silicon; and
a doped semiconductor material over the third semiconductor layer and the insulative collar, the doped semiconductor material having an opposite doping polarity relative to the doped well.

11. The photodetector structure of claim 10, wherein the doped semiconductor material includes a n-type dopant, and the doped well includes a p-type dopant.

12. The photodetector structure of claim 10, wherein the doped semiconductor material includes a p-type dopant, and the doped well includes a n-type dopant.

13. The photodetector structure of claim 10, further comprising:
a first insulative layer vertically between the doped semiconductor material and the doped well, the first insulative layer horizontally adjacent to each of the first, second, and third semiconductor layers;
a second insulative layer over the doped semiconductor material,
wherein the first insulative layer, the second insulative layer, and the insulative collar include an oxide;
a first contact structure electrically coupled to the doped semiconductor material, wherein the doped semiconductor material includes polysilicon; and
a second contact structure electrically coupled to the doped well, wherein the doped well is biased by the second contact structure.

14. The photodetector structure of claim 10, wherein the first, second, and third semiconductor material layers include undoped semiconductor material.

15. The photodetector structure of claim 10, wherein the insulative collar includes a first portion having a first horizontal thickness, and a second portion having a second horizontal thickness different than the first horizontal thickness.

16. A method of forming a photodetector structure, the method comprising:
forming a first semiconductor layer on a first portion of a doped well in a substrate;
forming an insulative collar laterally surrounding the first semiconductor layer, the insulative collar on the first portion of the doped well between the first semiconductor layer and a second portion of the doped well; and
forming a second semiconductor layer over the first semiconductor layer, wherein the insulative collar laterally surrounds the second semiconductor layer.

17. The method of claim 16, further comprising:
forming a third semiconductor layer over the second semiconductor layer; and
forming a doped semiconductor material over the third semiconductor layer and the insulative collar, the doped semiconductor material includes polysilicon having an opposite doping polarity relative to the doped well and the insulative collar includes an oxide.

18. The method of claim 17, wherein forming the first semiconductor layer includes epitaxial silicon, forming the second semiconductor layer includes epitaxial germanium, and forming the third semiconductor layer includes epitaxial silicon.

19. The method of claim 17, further comprising forming a trench isolation structure, wherein the first, second, and third semiconductor layers are formed within the trench isolation structure.

20. The method of claim 17, further comprising:
forming a first insulative layer vertically between the doped semiconductor material and the doped well;
forming a first contact structure electrically coupled to the doped semiconductor material; and
forming a second contact structure electrically coupled to the doped well, wherein the doped well is biased by the second contact structure.
